(19) United States
(12) Patent Application Publication
(10) Pub. No.: US 2017/0016140 A1
(43) Pub. Date: Jan. 19, 2017

(54) CRUCIBLE, FABRICATION METHOD OF THE CRUCIBLE, AND FABRICATION METHOD OF A CRYSTALLINE MATERIAL BY MEANS OF SUCH A CRUCIBLE

(71) Applicant: Commissariat à l'Energie Atomique et aux Energies Alternatives, Paris (FR)

(72) Inventors: Denis CHAVRIER, Chambéry (FR); Jean-Paul GARANDET, Saint-Cloud (FR); Etienne PIHAN, La Motte Servolex (FR)

(73) Assignee: COMMISSARIAT À L'ENERGIE ATOMIQUE ET AUX ENERGIES ALTERNATIVES, Paris (FR)

(21) Appl. No.: 15/124,319

(22) PCT Filed: Mar. 30, 2015
(86) PCT No.: PCT/FR2015/050818

§ 371 Date: Sep. 7, 2016

(30) Foreign Application Priority Data
Mar. 31, 2014 (FR) 1400784

(51) Int. Cl. C30B 11/00; C30B 29/06; H01L 31/18; B05D 7/22; B05D 3/00; B28D 5/04; C30B 11/02; C30B 33/00

(52) U.S. Cl. CPC C30B 11/002; C30B 11/02; C30B 29/06; C30B 33/00; B05D 7/22; B05D 3/007; B28D 5/04; H01L 31/1864; H01L 31/1804

(57) ABSTRACT

A crucible for formation of a crystalline material by solidification by growth on seed, including a bottom, at least one side wall orthogonal to the bottom of the crucible, and at least two marks extending on the inner surface of the at least one side wall in an orthogonal direction to the bottom of the crucible, for materialising the position of at least one seed designed to be positioned at the bottom of the crucible, the seed including at least first and second surfaces orthogonal to the bottom of the crucible. The respective positions of at least two of the marks on at least one of the side walls define, in the crystalline material, a first cutting plane tangent to the first surface of the seed and a second cutting plane tangent to the second surface of the seed.

### BACKGROUND OF THE INVENTION

The invention relates to a crucible for fabrication of a crystalline material by solidification and in particular by directional solidification. The invention also relates to the fabrication method of such a crucible, and the fabrication method of a crystalline material from such a crucible. The invention thus mainly concerns growth of silicon ingots for photovoltaic applications, but it can also be potentially applicable to any type of material having to be diced with precise dimensions on completion of a solidification method.

### State of the Art

In industrial practice, growth of a crystalline material can be achieved by directional solidification. Once the solidification is completed, the solidified material is then removed from the crucible and forms an ingot which has to be diced in the form of bricks. The edges of the ingot are generally contaminated by elements originating from the crucible. It is therefore judicious to remove the edges when performing dicing into crystalline bricks in order to only keep the centre of the ingot which is of good quality.

In the case of directional growth from a paving of monocrystalline seeds deposited in the bottom of the crucible, the crystalline material is melted above the seeds which will impose the crystalline orientation when solidification takes place. To guarantee the good electrical and mechanical quality of the crystalline bricks, the ingot should advantageously be diced at the level of the monocrystalline seed boundaries so as to relegate the defects induced at the level of these seed boundaries to the periphery of the bricks. This phase of dicing the ingot into bricks is delicate as the molten material has flowed in the whole of the crucible and the monocrystalline seed boundaries are no longer visible.

### Object of the Invention

An object of the invention is to produce a crucible for fabrication of a crystalline material by solidification by growth on seed having good electrical and mechanical qualities.

For this purpose, the crucible comprises a bottom and at least one side wall orthogonal to the bottom of the crucible, and means for materialising the position of at least one seed designed to be positioned at the bottom of the crucible, said seed comprising at least first and second surfaces orthogonal to the bottom of the crucible.

The means for materialising advantageously comprise at least two marks extending on the inner surface of the at least one side wall in an orthogonal direction to the bottom of the crucible.

Furthermore, the respective positions of at least two of the marks on at least one of the side walls define, in the crystalline material, a first cutting plane tangent to the first surface of said seed and a second cutting plane tangent to the second surface of said seed.

The invention also relates to a method for producing one such crucible, the method comprising the following steps:
providing a crucible comprising at least a bottom and at least one side wall orthogonal to the bottom of the crucible,
forming at least two marks in a direction orthogonal to the bottom of the crucible on the inner surface of at least one of the side walls of the crucible.

The invention finally relates to the method for fabricating a brick of crystalline material by solidification by means of such a crucible, the method comprising the following steps:
providing a crucible comprising the above-mentioned features,
performing a directional solidification operation comprising placing of at least one monocrystalline seed in the bottom of the crucible by means of at least two of the marks to form an ingot of crystalline material in the crucible,
extracting the ingot from the crucible,
dicing the crystalline material ingot along the first cutting plane and the second cutting plane, the first and second cutting planes coinciding with the planes of the monocrystalline seed boundaries, so as to obtain at least one brick.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 is a perspective view of a crucible according to a particular embodiment of the invention,

FIGS. 2 and 3 represent two different embodiments of the crucible of FIG. 1,

FIG. 4 illustrates in top view the manner in which the monocrystalline seeds are positioned in the crucible,

FIG. 5 represents dicing of the ingot after take-out from the crucible.

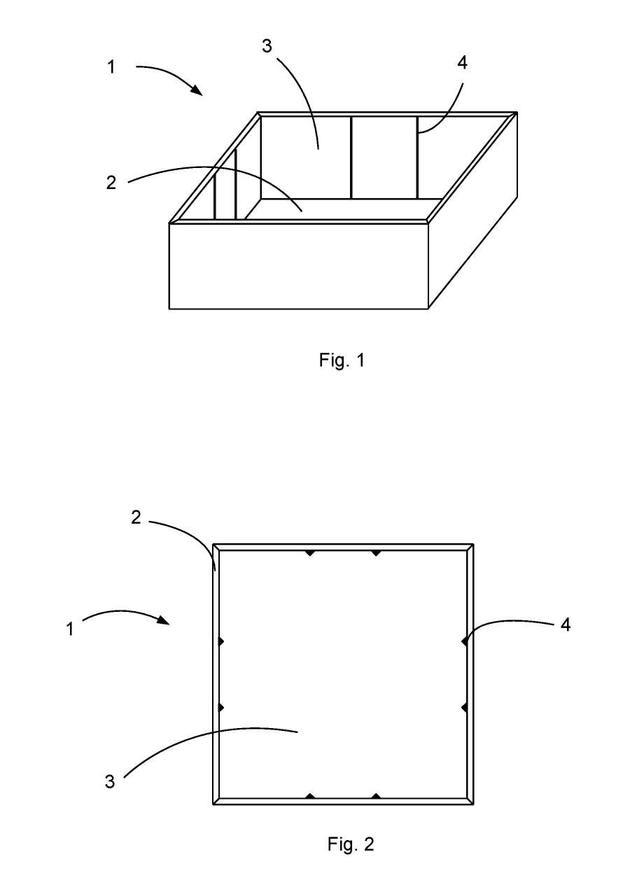

### DETAILED DESCRIPTION

A crucible 1 is conventionally used to form an ingot of crystalline material by solidification by growth on seed, and in particular by directional solidification. The crystalline material can for example be a semiconductor material such as silicon or germanium. It can also be an oxide, for example aluminium oxide (sapphire). The crucible 1 advantageously comprises a bottom 2 and at least one side wall 3 orthogonal to the bottom 2. According to a particular embodiment illustrated in the figures, the crucible 1 can for example comprise four side walls 3, so as to form a rectangular crystalline ingot advantageously having the shape of a rectangular parallelepiped or of a cube. The shape of the crucible 1 facilitates dicing of the ingot into bricks as will be seen further on. But it can for example be easily envisaged to use a crucible of any shape, for example a cylindrical crucible.

The crucible 1 is advantageously provided with means for materialising the position of at least one seed designed to be positioned at the bottom of the crucible before formation of the crystalline material by solidification by growth on seed. The means for materialising can comprise at least two marks 4 on the inner surface of the side wall 3 of the crucible 1, advantageously positioned along an axis orthogonal to the bottom 2 of the crucible 1. The positions of at least two of these marks 4 are chosen so as to define first and second cutting planes of the crystalline ingot obtained by solidification by growth on seed. Once solidified, the ingot in fact comprises the imprint of the marks 4 on its side walls, so that determination of the cutting planes is facilitated.

Each cutting plane is advantageously tangent to one of the surfaces of a seed positioned at the bottom of the crucible before directional solidification, and passes through one of the marks 4.

Advantageously, the first mark 4 can be positioned so that the first cutting plane is orthogonal to a plane tangent to the inner surface of the side wall 3. When the seed has the shape of a rectangular parallelepiped, the second cutting plane is for its part orthogonal to the first cutting plane and passes through a second mark 4.

If the crucible 1 comprises two perpendicular adjacent side walls, at least two of the marks 4 can be respectively positioned on two adjacent side walls 3. In this case, the first cutting plane can then be advantageously parallel to a first side wall 3, and the second cutting plane parallel to a second side wall 3 adjacent to the first side wall. This configuration of the crucible 1 is particularly advantageous to form ingots of parallelepipedic shape, of rhomboid shape or of cubic shape.

According to a particular embodiment, the crucible 1 can comprise at least one additional mark, advantageously positioned facing one of the marks 4, for example on a side wall 3 opposite the side wall comprising the mark 4 when the crucible 1 is a parallelepiped. Positioning two marks 4 facing one another enables the position of the cutting plane of the ingot after solidification to be determined with enhanced precision.

When the crucible 1 is used to perform solidification by growth on seed, it can comprise positioning means (not shown) at the bottom of the crucible 1. The role of these means is to enable the seeds to be placed in predefined positions with respect to the marks 4. These positioning means are for example those described in International Patent application WO 2013/034819, i.e. holes for positioning the seeds. They can also be in the form of marks such as grooves, ribs, or studs facilitating placing of the seeds.

According to the illustrated embodiment, the marks 4 advantageously extend over the whole height of the inner surfaces of the side walls 3 in an orthogonal direction to the bottom 2 of the crucible 1.

However, each mark 4 can extend over a part of the height of the inner surfaces of the side walls 3 only, for example from the bottom 2 of the crucible or from the top edge of the side walls 3. The length of each mark 4 is greater than 10% of the height of the side walls 3, preferably greater than 30% of the height of the side walls 3, and advantageously greater than 50% of the height of the side walls 3. The marks 4 can also be continuous or discontinuous and present different heights.

Each mark 4 of the crucible 1 can therefore have characteristics which are proper to it, for example when the crucible 1 is designed for solidification of several types of crystalline materials having properties which differ, thus resulting in different possible dicings of the ingot.

The position of each mark 4 can be judiciously chosen according to the type of solidification performed and according to the type of material to be solidified. Marks 4 can be placed a few centimetres from the ends of the side walls 3 in order to only keep the central part of the ingot when dicing is performed. The edges of the ingots are in fact generally contaminated by elements originating from the crucible 1 and are therefore of less good quality of use. This phenomenon is in particular well known in the case of silicon for photovoltaic applications where the edges of the ingot are referred to as red zone. The marks 4 enable centring of the crystalline bricks which are diced in the ingot to be performed in order to ensure the quality of the latter and to ensure the reproducibility of positioning of the ingot when dicing of the latter is performed.

The ingot should advantageously be diced at the level of the monocrystalline seed boundaries so as to relegate the defects induced at the level of these seed boundaries to the periphery of the bricks.

When directional solidification is performed by growth on seeds, it may be useful to place the marks 4 at the level of the edges of the monocrystalline seeds so as to relegate the defects induced in the crystal at the level of these seed boundaries to the periphery of the bricks and to improve their mechanical and electrical quality. Thus, when dicing is performed, the defects are eliminated without the user having to look for indications of solidification on the top and bottom surfaces of the ingot.

In the photovoltaic field, the bricks used are advantageously in the shape of a rhomboid or a cube the sides of which generally have dimensions comprised between 50 and 200 mm. Solar panels comprise for example cells having a standard size which is equal to 156 mm per side.

Also, to form bricks used in the photovoltaics field, the crucible 1 can advantageously comprise marks 4 placed on its inner side wall 3 so that two consecutive marks of one and the same side wall 3 are separated by a distance of 50 to 200 mm and preferably by a distance of 156 mm. By placing seeds having these characteristic dimensions at the bottom of the crucible 1 by means of the marks 4, crystalline bricks with ideal dimensions and having very good mechanical and electrical properties can then be formed.

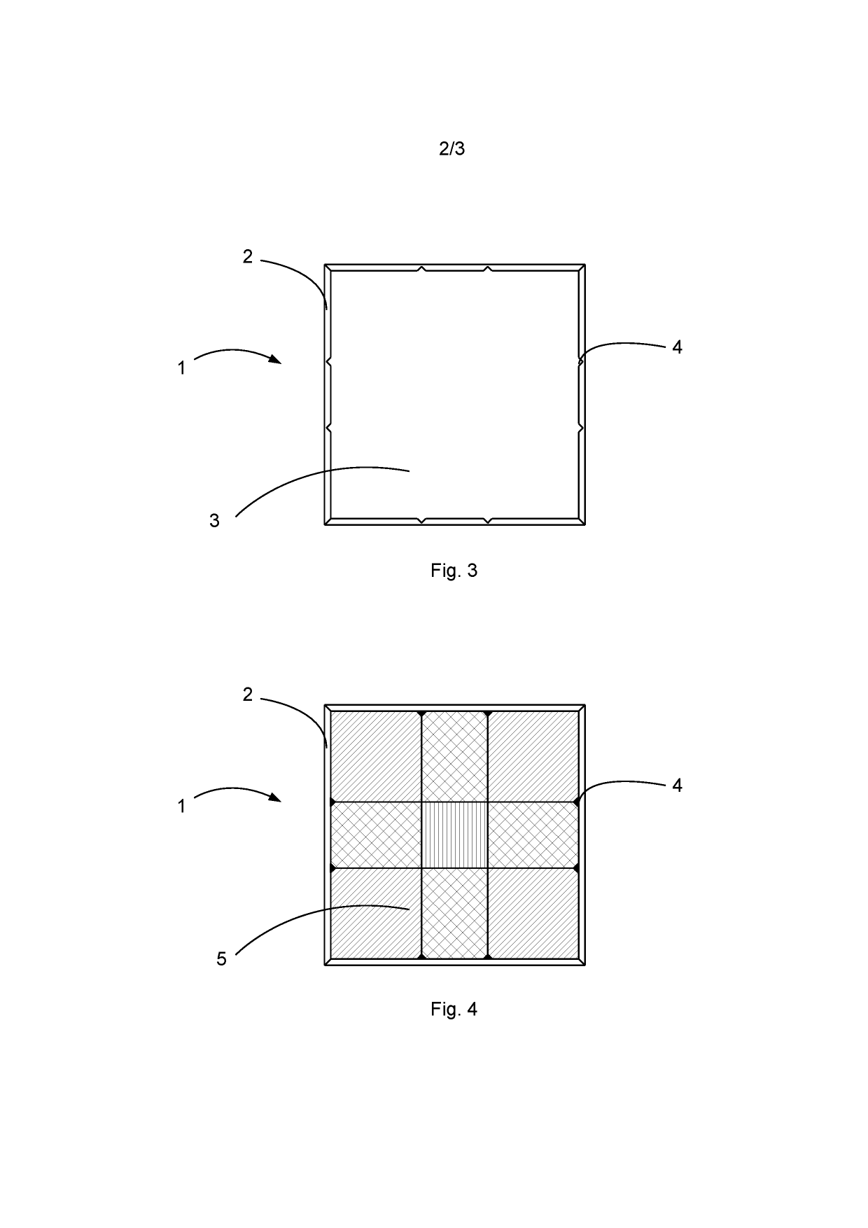

According to the embodiments illustrated in FIGS. 2 and 3, the marks 4 can be ribs, i.e. saliences formed by an additional thickness, or grooves, i.e. indents formed by a smaller thickness on the side walls 3 of the crucible 1. The use of ribs is preferred in particular when the crucible is made from silicon oxide and the crystalline material is silicon. It is on the contrary advantageous to use grooves on crucibles made from graphite.

When the marks 4 are ribs, the imprints left on the crystalline ingot are then grooves, i.e. indents. On the contrary, when the marks 4 are grooves, the imprints left on the ingot are ribs, i.e. saliences.

The grooves can for example be formed by machining of the inner surfaces of the side walls 3, or by etching through a mask by means of any conventional lithography technique. What is meant by machining is mechanical removal of the material forming the crucible. What is meant by etching is chemical elimination, for example a HF solution for a silica crucible. The grooves preferentially have a depth of less than 2 mm.

In the case where the marks 4 are ribs, the latter can be made using a template (not shown) enabling a homogeneous shape to be given over the whole length of the marks 4. An additional deposition of material is then performed on an inner surface of a side wall 3 of the crucible 1. The ribs are salient over a thickness preferentially smaller than 2 mm.

The marks 4 can advantageously have a triangular shape, and in particular the shape of an isosceles triangle. This triangular shape is visible in a plane parallel to the bottom 2 of the crucible 1. A template of suitable size and shape can for example enable the formation of ribs advantageously having a cross-section the base of which, i.e. the width of the rib, measures between 100 μm and 6 mm, and preferentially between 500 μm and 2 mm, and the angle of which at the peak is comprised between 30° and 120°, preferentially between 45° and 90°. These dimensions form a good trade-off between the fabrication constraints of the ribs and the precision of positioning of the cutting plane of the ingot.

The ribs can for example be formed by localised deposition of a solution containing a powder compatible with the material to be crystallised, and heat treatment enabling sintering of the powder. For example if the material to be crystallised is Si, the powder can be Si₃N₄.

The crucible 1 can advantageously be used in a crystallisation furnace (not shown) in which a solidification heat gradient is applied during the directional solidification operation in order to perform growth of the crystalline material. This heat gradient is advantageously applied in a direction orthogonal to the bottom 2 of the crucible, the temperature being progressively colder as the bottom 2 of the crucible 1 is approached.

The invention also relates to the fabrication method of a crucible 1. The latter can be implemented from a crucible of any shape and of any size. It can for example be made from silica or from graphite (crystallisation of the semiconductors) or from precious metals (crystallisation of the oxides). Whether the crucible is reusable or not, it is deformed during the melting and solidification phases of the material.

Indeed, when the crucible 1 is subjected to a temperature gradient, for example a temperature increase of about 1500° C., the resultant of the forces exerted by the molten material on the side walls 3 deforms the angles of the crucible 1 which become more acute, and pushes the side walls 3 towards the outside of the crucible 1. The temperature then decreases, and the volume of the crystalline ingot decreases when the latter solidifies.

For example, silica crucibles undergo a vitreous transition followed by solidification during crystalline growth of the material. These phase changes generate variations of about 2% between the initial and final dimensions of the crucible, these variations being dependent on the exact composition of the crucible. It is therefore impossible to draw up a deformation abacus of the crucible during crystalline growth of the material. The presence of the marks 4 enables the position of the dicing to be defined precisely independently from the deformation of the ingot. The dimensions of the marks 4 (thickness of the rib or depth of the groove) are furthermore sufficiently small not to have any influence on the variations of dimension of the crucible during the phase changes of the latter.

When directional solidification by growth on seeds is performed, the position of the seeds in the crucible before dicing is not known with certainty. Another purpose of the marks 4 is to keep the memory of the position of the seeds after the crystallisation cycle.

In order to minimise the uncertainties of positioning of the marks 4 on the side walls 3, it may be advantageous to form the marks 4 in areas of the side walls 3 which deform little, for example close to the centre of the latter if the crucible 1 is of parallelepipedic shape.

To achieve a crucible 1 as described above, a crucible is used comprising at least a bottom 2 and at least one side wall 3 orthogonal to the bottom 2, and at least two marks 4 orthogonal to the bottom 2 are formed on the inner surfaces of at least one of the side walls 3.

The marks 4 can be made in continuous manner starting from the bottom 2 or from the top edge of the side walls 3, or in discontinuous manner on the side walls 3. Their lengths can be greater than at least 10% of the total height of the side walls 3, preferentially over lengths greater than 30%, even more preferentially over lengths greater than 50%, and advantageously over the whole height of the side walls 3.

The marks 4 can advantageously have a triangular cross-section so as to be able to mark the cutting line of the ingot precisely. The base of the triangular cross-section can for example be comprised between 100 μm and 6 mm, and the angle at the peak can be comprised between 45° and 90°.

At least one of the marks 4 can be a groove formed for example by machining of one of the inner surfaces of the side walls 3, or by etching by means of conventional lithography techniques. In alternative manner, the marks 4 can advantageously be ribs produced by means of a template.

When the crucible 1 is made from silicon oxide and the material to be crystallised is silicon, the marks 4 can advantageously be formed by means of a material comprising Si₃N₄ powder. To form the ribs, 35% to 55% of Si₃N₄ powder, 1% to 4% of polyvinyl alcohol, and deionized water is advantageously mixed together. This mixture is applied locally on the inner surfaces of the side walls 3 of the crucible 1 by means of the template to form the marks 4. This mixture has to be sufficiently viscous so as not to flow or spread when it is applied on the side walls 3 of the crucible 1.

The assembly is then annealed in a furnace heated to a temperature comprised between 900° and 1200° C., preferentially between 1000° C. and 1100° C. The anneal time is comprised between 30 min and 4 h, preferentially between 1 h and 3 h.

According to an exemplary embodiment for growth of silicon for photovoltaic applications, it is possible to make marks 4 on a silica crucible 1 of G2 size. The marks 4 are ribs comprising 43% of Si₃N₄ powder, 2.3% of polyvinyl alcohol, and deionized water. After formation of the ribs by means of the template, the crucible 1 is annealed in a furnace at 1050° C. for 2 h. As Si₃N₄ has anti-adhesive properties, this makes take-out of the ingot after crystallisation easier.

To produce a brick 5 of crystalline material by means of a crucible 1 as described above, the material, for example silicon, is placed in the crucible 1 and the assembly is then placed in a crystallisation furnace such as the one referred to in the foregoing. The thermal gradient is applied in the crystallisation furnace, and this gradient is advantageously directed in an orthogonal direction to the bottom 2 of the crucible 1. The material undergoes a melting phase followed by a solidification phase.

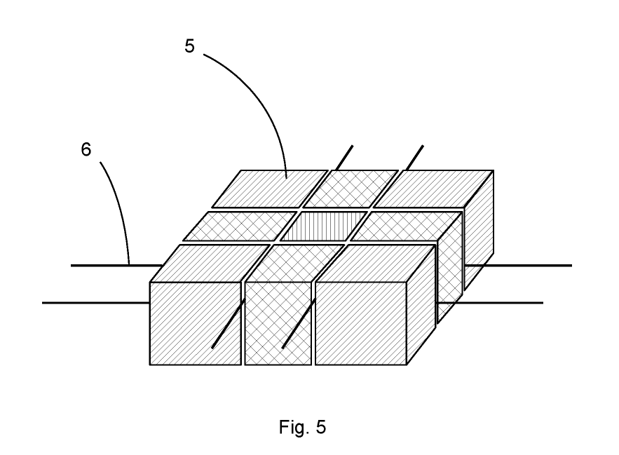

The ingot is then taken out from the mould when the material is completely crystallised. Traces due to the marks 4 appear on the side walls of the ingot. The traces are used to position cutting wires or blades 6 in correct manner along the first and second cutting axes so as to obtain crystalline bricks, for example crystalline silicon bricks. This step of fabrication of the bricks 5 is illustrated in FIG. 5.

According to a particular fabrication method of the crystalline bricks, directional growth by growth on seeds can be used. In this method, at least one monocrystalline seed is deposited on the bottom 2 of the crucible 1 advantageously using the positioning means of the seeds on the bottom 2 of the crucible 1. The positioning means can for example be marks 4 placed in positions on the side walls 3 of the crucible 1 which are chosen to be suitable for the dimensions of the seeds.

Then, in the ingot dicing step, the traces left by the marks 4 advantageously enable the cutting planes to be made to coincide with the planes of the boundaries of the monocrystalline seeds.

According to a particular embodiment, additional cutting planes can be chosen in order to perform one or more additional dicing steps. Two additional cutting planes can for example be used, these two additional planes advantageously being parallel to the first and second cutting planes. The additional cutting planes can be positioned for example by means of additional marks 4 placed on the side walls 3 of the crucible 1. They can also be determined from the position of the first and second cutting planes.

For example, in the embodiment represented in FIGS. 4 and 5, five seeds of square shape and four seeds of rectangular shape are used to form the crystalline material by directional solidification. The seeds are arranged so as to occupy the whole of the bottom 2 of the crucible 1, and eight marks 4 have advantageously been placed on the side walls 3 of the crucible 1 at the level of the junctions between the seeds. After crystallisation of the ingot, the latter is taken out from the mould and diced into bricks along four cutting planes parallel two by two, the cutting planes coinciding with the planes of the seed boundaries.

Crystalline bricks are thus obtained devoid of grain boundaries, or having grain boundaries relegated to the periphery of the crystalline bricks. The latter thus have a high electrical and mechanical quality and meet the demands required in the photovoltaic field.

1-20. (canceled)

21. Crucible for formation of a crystalline material by solidification by growth on seed, comprising
a bottom,
at least one side wall orthogonal to the bottom of the crucible,
and at least two marks extending on the inner surface of the at least one side wall in a direction orthogonal to the bottom of the crucible, for materialising the position of at least one seed designed to be positioned at the bottom of the crucible, said seed comprising at least first and second surfaces orthogonal to the bottom of the crucible,
wherein the respective positions of at least two of the marks on at least one of the side walls define, in the crystalline material, a first cutting plane tangent to the first surface of said seed and a second cutting plane tangent to the second surface of said seed.

22. Crucible according to claim 21, comprising at least two perpendicular adjacent side walls, and wherein at least two of the marks are respectively positioned on two of the perpendicular adjacent side walls.

23. Crucible according to claim 21, configured to form a crystalline brick of parallelepipedic shape, of rhomboid shape or of cubic shape.

24. Crucible according to claim 21, wherein at least two of the marks are positioned on one and the same side wall, and are separated by a distance comprised between 50 and 200 mm.

25. Crucible according to claim 21, comprising at least one additional mark positioned facing one of the marks on a side wall opposite the side wall comprising said mark.

26. Crucible according to claim 21, wherein at least one of the marks presents a length greater than or equal to 10% of the height of the corresponding side wall.

27. Crucible according to claim 21, wherein at least one of the marks has a triangular cross-section in a cutting plane parallel to the bottom.

28. Crucible according to claim 27, wherein the cross-section of at least one of the marks is in the form of an isosceles triangle.

29. Crucible according to claim 27, wherein the base of the triangular cross-section is comprised between 100 μm and 6 mm, and wherein the angle at the peak of the triangular cross-section is comprised between 45° and 90°.

30. Crucible according to claim 21, wherein at least one of the marks is a groove in the inner surface of the side wall.

31. Crucible according to claim 21, wherein at least one of the marks is a rib in the inner surface of the side wall.

32. Method for fabricating a crucible according to claim 21, comprising the following steps:
providing a crucible comprising at least a bottom and at least one side wall orthogonal to the bottom of the crucible,
forming at least two marks in a direction orthogonal to the bottom of the crucible on the inner surface of at least one of the side walls of the crucible.

33. Method for fabricating a crucible according to claim 32, wherein at least one of the marks is formed over a length greater than 10% of the height of at least one of the side walls.

34. Method for fabricating a crucible according to claim 32, wherein formation of at least one of the marks is performed by addition of material in a template so as to form a rib, or by etching so as to form a groove.

35. Method for fabricating a crucible according to claim 32, wherein formation of at least one of the marks is performed by local deposition of a solution containing particles of Si₃N₄ on the inner surface of the side wall of the crucible followed by annealing of the crucible so as to form a rib.

36. Method for fabricating a crucible according to claim 35, wherein the solution comprises 35 to 55% of Si₃N₄, 1% to 4% of polyvinyl alcohol, and deionised water.

37. Method for fabricating a crucible according to claim 35, wherein annealing is performed at a temperature comprised between 900° and 1200° C., for a time comprised between 30 min and 4 h.

38. Method for producing a brick of crystalline material by directional solidification comprising the following steps:
providing a crucible according to claim 21,
performing a directional solidification operation comprising placement of at least one monocrystalline seed at the bottom of the crucible by means of at least two marks, to form a crystalline material ingot in the crucible,
extracting the ingot from the crucible,
dicing the crystalline material ingot along the first cutting plane and along the second cutting plane, the first and second cutting planes coinciding with the planes of the monocrystalline seed boundaries, so as to obtain a brick.

39. Method according to claim 38, wherein the crystalline material is silicon.

40. Method according to claim 38, comprising an additional dicing step along two additional cutting planes respectively parallel to the first and second cutting planes.
